(19) United States
(12) Patent Application Publication
(10) Pub. No.: US 2013/0070901 A1
(43) Pub. Date: Mar. 21, 2013

(54) OPTIMIZED SWITCHING FOR A MULTILEVEL GENERATOR

(71) Applicant: Tobias Grassl, Erlangen (DE)

(72) Inventor: Tobias Grassl, Erlangen (DE)

(73) Assignee: Siemens Aktiengesellschaft, Munchen (DE)

(21) Appl. No.: 13/622,221

(22) Filed: Sep. 18, 2012

(30) Foreign Application Priority Data
Sep. 19, 2011 (DE) 10 2011 082 946.6

(51) Int. Cl. H03K 3/00; H05G 1/32

(52) U.S. Cl. 378/111; 327/108

(57) ABSTRACT

A method for the generation of drive signals for a multilevel generator comprising a number of cells that may be switched independently of each other is provided. Each of the cells is provided to output a cell voltage based on a respective drive signal. The drive signals of the cells overall output a multilevel quantized reference signal. The method includes splitting the multilevel quantized reference signal such that at least two drive signals of different cells contribute to a quantization level of the quantized reference signal in a predetermined period.

This application claims the benefit of DE 10 2011 082 946.6, filed on Sep. 19, 2011.

### BACKGROUND

The present embodiments relate to a method for the generation of drive signals for a multilevel generator.

Multilevel generators are known, for example, from the publication of Leon M. Tolbert et al., “Charge Balance Control Schemes for Cascade Multilevel Converter in Hybrid Electric Vehicles,” IEEE TRANSACTIONS ON INDUSTRIAL ELECTRONICS, Vol. 49, No. 5, October 2002, pages 1058 to 1064. This relates to cascaded power sources such as those found, for example, in a multilevel H-bridge converter. The cascaded power sources are able to generate high output voltages based on a quantized reference signal. Every multilevel generator includes energy-output cells (e.g., cells) such as, for example, energy storage cells in the form of batteries or capacitors. During an active phase, a number of cells is selected and applied as a series circuit to the output of the cascaded energy transducer in order to generate a specific voltage level depending upon the quantized reference signal. The connection and/or disconnection of cells to or from the series circuit during the active phase enables the output voltage to emulate the shape of the quantized reference signal. Outside the active phase, the cells may be recharged with energy for the next active phase. Alternatively, depending on the topology, the individual cells may also be charged during the active phase.

### SUMMARY AND DESCRIPTION

The present embodiments may obviate one or more of the drawbacks or limitations in the related art. For example, the drive circuit of known multilevel generators is improved.

The drive signals used for individual cells of a multilevel generator may be generated such that at least two drive signals of different cells contribute to a quantization level of a quantized reference signal in a predetermined period so that an electrical energy output of the individual cells is mutually harmonized to generate the output voltage.

In known multilevel generators, during an active phase, each cell is provided to generate a specific quantization level of the output signal based on the quantized reference signal. This has the drawback that cells used to generate lower quantization levels are more greatly loaded than cells for higher quantization levels of the output voltage. If the output voltage, and hence also the quantized reference signal, has a quantized sinusoidal shape, the electrical energy flow out of the cell contributing to the maximum quantization level is much lower than the electrical energy flow out of the cell contributing to the lowest quantization level. However, the cells are thus exposed to different loads, which has the result that the cells contributing to the lower quantization levels in the output signal display signs of failure earlier than cells contributing to the higher quantization levels in the output signal.

In order to be able to avoid these signs of failure, the individual cells may be designed with different degrees of resistance, but this results in higher costs, for example, with respect to production costs, since a separate production method would be used for each cell in the multilevel generator. In addition, the structure of the multilevel generator would then be subject to certain restrictions because the series circuit of the individual cells is no longer optionally expandable.

Load compensation among the cells is achieved using a suitable generation of the drive signals of the individual cells. This takes place in that the individual drive signals of the cells are selected such that at least two drive signals contribute to a single quantization level in the quantized reference signal so that the cell voltage of at least two cells of the multilevel generator contributes to one single quantization level of the quantized output voltage of the multilevel generator. In this way, for example, the on-periods of the cells, which conventionally contribute to a low quantization level, are shortened, and correspondingly, the on-periods of the cells, which conventionally contribute to a higher quantization level, are extended. Alternatively or additionally, the number of switching operations of the cells that conventionally contribute to a low quantization level may be reduced, and correspondingly, the number of switching operations of the cells that conventionally contribute to a higher quantization level may be increased.

In one embodiment, a method for the generation of drive signals for a multilevel generator is provided. The multilevel generator includes a number of energy output cells (e.g., cells) that may be switched independently of each other. Each of the cells is provided to output a cell voltage based on a respective drive signal. Overall, the drive signals of the cells output a multilevel quantized reference signal. The method disclosed includes splitting the multilevel quantized reference signal such that at least two drive signals of different cells contribute to a quantization level of the quantized reference signal in a predetermined period.

The cell may be any electrical device suitable for outputting electrical energy. Suitable cells are, for example, capacitor cells that may be controlled independently of each other (e.g., capacitor cells used in a modified Marx generator) and also accumulator cells used, for example, in a multilevel converter to supply electrical energy to an electric motor in a hybrid vehicle. Together with an energy return unit in the vehicle, the multilevel converter forms the multilevel generator. In each case, the drive signals generated by the method disclosed enable the electrical energy output of the individual cells to be harmonized with the multilevel generator during the generation of an output voltage.

In one embodiment, the quantized reference signal is made up of a number of periodic partial signals that is smaller than or equal to the number of cells. The periodic partial signals may be generated in any way wanted. For example, the partial signals may be provided directly from a microcontroller under the stated condition that the sum total produces the quantized reference signal. Alternatively, the analog version of the quantized reference signal may be pulse-width modulated using ramp signals. The number of ramp signals corresponds to the number of cells used, and the individual ramp signals are displaced with respect to each other by an offset (e.g., uniformly). From a technical viewpoint, the individual partial signals represent the signal shape of a quantization level in the quantized reference signal and hence the voltage shape of a quantization level in the output voltage of the multilevel generator.

In one embodiment, the reference signal and the partial signals may be periodic, and the method disclosed may also include the act of allocating the periodic partial signals to the drive signals in each period of the quantized reference signal. The specific period is a multiple of the period of the reference signal. Under the stated condition that more than one drive signal is to contribute to one quantization level, this provides that, in different periods of the quantized reference signal, the driving of the individual cells takes place on the basis of different partial signals. The advantage of the allocation of the periodic partial signals to the drive signals in each period of the quantized reference signal is that the control or regulation method does not have to be adapted to generate the drive signals.

In another embodiment, for the allocation of the periodic partial signals to the drive signals, after each period of the quantized reference signal, the periodic partial signals may be exchanged such that after a specific number of periods of the quantized reference signal corresponding to the number of cells used in the multilevel generator, each cell has switched each partial signal once, and hence each voltage level in the output signal. With a constant output voltage of the multilevel generator averaged over the number of active phases, this provides a constant load of all cells.

In another embodiment, the periodic partial signals may be apportioned to the drive signals such that, over two periods of the quantized reference signal, the cells have experienced approximately the same load corresponding to the average load of all cells.

In one embodiment, the sequence in which the periodic partial signals are apportioned to the drive signals may be fixed. For example, the loads on the individual cells may be determined once in advance with a known output voltage of the multilevel generator, and the splitting of the quantized reference signal may be performed durably according to a fixed scheme. The scheme and hence the sequence of the allocation of the partial signals to the individual drive signals may, for example, be stored in a memory logic circuit. The memory logic circuit may be used to re-allocate the periodic partial signals to the individual drive signals by corresponding transposition after each period of the quantized reference signal. More simply, the scheme may also be configured so that, after each period of the quantized reference signal, the individual periodic partial signals are also exchanged sequentially and allocated to the individual drive signals. The result of this is that the drive signals for each cell (e.g., under the condition that the quantized reference signal is periodic) repeat all periods of the quantized reference signal corresponding to the number of cells.

In one embodiment, the losses for each individual periodic partial signal may be determined. The losses may be made up of the switching losses per switching operation, the losses by the current load over the on-period of each cell in dependence on the voltage of each cell, in the case of a varying load, in dependence on the load, or a combination thereof. While the switching losses may, for example, be determined by a counter that counts the number of switching operations of a cell in a period of the quantized reference signal, the losses due to the current load may, for example, be determined by a time measurement for the on-period of each cell in a period of the quantized reference signal. On the basis of these losses, algorithmic methods may be used to apportion the periodic partial signals to the individual cells such that the average load on all cells is the same. This algorithmic method may, for example, allow for the fact that, with semiconductor switches, the switching losses may be much greater than the losses caused by the current load (e.g., conduction losses). If the cells are embodied as capacitor cells such as, for example, in a Marx generator, normally, at higher frequencies, the losses in the capacitors are lower than the losses in the active semiconductors. Thus, the switching losses in the semiconductors may only be determined. Hence, time measurement for the switching time may not be necessary. The situation is different if a battery is to be used as a cell, for example, or very low frequencies are to be used.

In an alternative or additional further development, the method may also include splitting of the quantized reference signal into the drive signals such that the drive times of the individual cells in the predetermined period are the same. This has the advantage that the harmonization of the cell loads may be achieved independently of whether the reference voltage is periodic or aperiodic. The predetermined period may be selected as short or as long as desired. The longer the predetermined period, the more uniform the long-term load on the individual cells of the multilevel generator. A disclosed method with a shorter predetermined period is characterized by a lower calculation and memory requirement.

The cells of the multilevel generator are, for example, buffer memories that, for example, accept electrical energy in a Marx generator from a voltage source or in a hybrid vehicle from an energy return unit during a charging phase and output this electrical energy during an active phase to an electrical load. Alternatively, in other topologies, the buffer memories may also be recharged during the active phase so that there is no passive phase or charging phase at all. If there is a passive phase, the predetermined period may be set as equal to an active phase. The result of this is that the loads of the cells are harmonized within an active phase so that not only are the individual cells permanently equally loaded, the peak load of the individual cells is also reduced. In the case of multilevel generators with cells in the form of capacitors, this also has the advantage that the voltage drop due to the discharge at the individual cells is lower, and the capacitance of the capacitors may be dimensioned for a lower average on-period per active phase of the individual cells. Alternatively, the capacities may be set lower and hence more inexpensively, thus enabling production costs to be saved. The allocation of the switching losses may also increase the switching frequencies.

In another embodiment, the method includes the determination of a positive edge or a negative edge of the partial signals or of the quantized reference signal in the predetermined period and the activation or deactivation of the drive signal belonging to a cell with the shortest or longest drive time. This provides that when a positive edge is determined in the partial signals, the drive signal of the cell with the shortest on-period is activated, and when a negative edge is determined in the partial signal, the cell with the longest on-period is deactivated. The generation of the drive signals based on the edges of the partial signals enables substantially the same on-period of the individual cells to be achieved. The length of the on-period of the individual cells may be determined by recording. In this way, the generation of the drive signals does not need to be defined in advance. The individual drive signals are generated in dependence on the shape of the quantized reference signal such that the electrical energy flow out of the cells and hence the cell voltage as a contribution to the output voltage of the multilevel generator are harmonized. For example, in the case of cells made up of capacitors, the harmonization of the drive times in the drive signals achieves optimization of the conduction losses caused by parasitic effects in and on the energy storage cell and mutually harmonic discharge of the individual cells in the multilevel converter.

Alternatively or additionally, in another embodiment, a positive edge or a negative edge of the partial signals in the predetermined period may be determined, and the drive signal belonging to a cell with the fewest switching operations is activated or deactivated. This provides, regardless of whether a positive or negative edge is determined, that the drive signal of the cell with the least number of switching operations will always be activated or deactivated. The number of the switching operations may, for example, be determined by one counter per cell. Taking into account the number of switching operations enables, additionally or alternatively to the conduction losses, the switching losses to be taken into account upon generation of the drive signals.

In one embodiment, the cell with the shortest or longest drive time is determined first before the cell with the fewest switching operations. In this way, the drive times are prioritized. This is advantageous with cells, in which the conduction losses dominate the switching losses. This is also advantageous if the total capacitance of memories is to be better utilized.

In one embodiment, the cell with the fewest switching operations is determined first before the cell with the shortest or longest drive time. In this way, the number of switching operations is prioritized. This is, for example, advantageous if the cells are embodied as capacitor cells and switched via semiconductor switches with high frequencies. In this case, the conduction losses in the capacitors and in the semiconductor switches are lower than the switching losses in the active semiconductors.

In a further embodiment, the method includes the act of resetting the number of switching operations and/or switching periods of each cell following the expiry of the predetermined period. This is advantageous for a common multilevel generator that resets the individual cells to a common state of charge as a reference condition after an active phase. Counters with few counting positions may then be used in these generators.

In another embodiment, the drive time of two cells is the same if the respective drive times lie within a predetermined tolerance band. The tolerance band enables the losses in the multilevel generator to be further reduced if, on a prioritization of the drive times, two cells have insignificant on-period differences but high differences in the switching operations. The tolerance band may soften the priority.

In the same way, the switching operations of two cells may be set the same if the respective switching operations lie within a predetermined tolerance band. This may result in the same effect if the two cells have virtually the same number of switching operations but a large difference in the on-periods.

In an additional or alternative further development, the method includes weighting the drive times or the number of the switching operations of the individual cells with a weighting factor. The weighting factor enables the drive times to be compared with each other (e.g., with respect to the load at the time of driving).

In one embodiment, the weighting factor may be dependent on the output current, on the output voltage of the multilevel converter, and/or on the voltage of the respective active cell at the time of the determination of the drive time. The output voltage does not have to be explicitly measured. The output voltage may also be calculated by adding together the cell voltages of the individual active cells. The formation of the weighting factor in this way may reduce the influence of linear loads at the output of the multilevel generator on the decision as to which cell is the next to contribute to the output voltage of the multilevel generator.

A device that is suitable for the embodiment of a disclosed method is also provided. The device, for example, includes a memory (e.g., a non-transitory computer-readable medium) and a processor. The method is stored in the memory in the form of a computer program, and the processor is provided for the embodiment of the method when the computer program is loaded from memory into the processor.

A circuit including a multilevel converter with cells that may be switched independently of each other is also provided. The cells are each provided to output a cell voltage based on a respective drive signal and a disclosed device.

An X-ray device including an X-ray source and a circuit supplying the X-ray source with electrical energy is also provided.

### BRIEF DESCRIPTION OF THE DRAWINGS

FIG. 1 shows a circuit diagram of one embodiment of a multilevel generator based on a Marx generator;

FIG. 2 shows the multilevel generator from FIG. 1 in a state of charge;

FIG. 3 shows the multilevel generator from FIG. 1 in a first state of discharge;

FIG. 4 shows the multilevel generator from FIG. 1 in a second state of discharge;

FIG. 5 shows the multilevel generator from FIG. 1 in a third state of discharge;

FIG. 6 shows a diagram with an exemplary quantized reference signal for the output voltage to be generated by the multilevel generator;

FIG. 7 shows a diagram with an example of drive signals for the multilevel generator;

FIG. 8 shows a diagram with a further example of drive signals for the multilevel generator;

FIG. 9 shows a flowchart with one embodiment of a method to generate the drive signals for the multilevel generator;

FIG. 10 shows a diagram with an example of drive signals generated with one embodiment of the method according to FIG. 9; and

FIG. 11 shows a diagram with a further example of drive signals generated with one embodiment of the method according to FIG. 9.

### DETAILED DESCRIPTION OF THE DRAWINGS

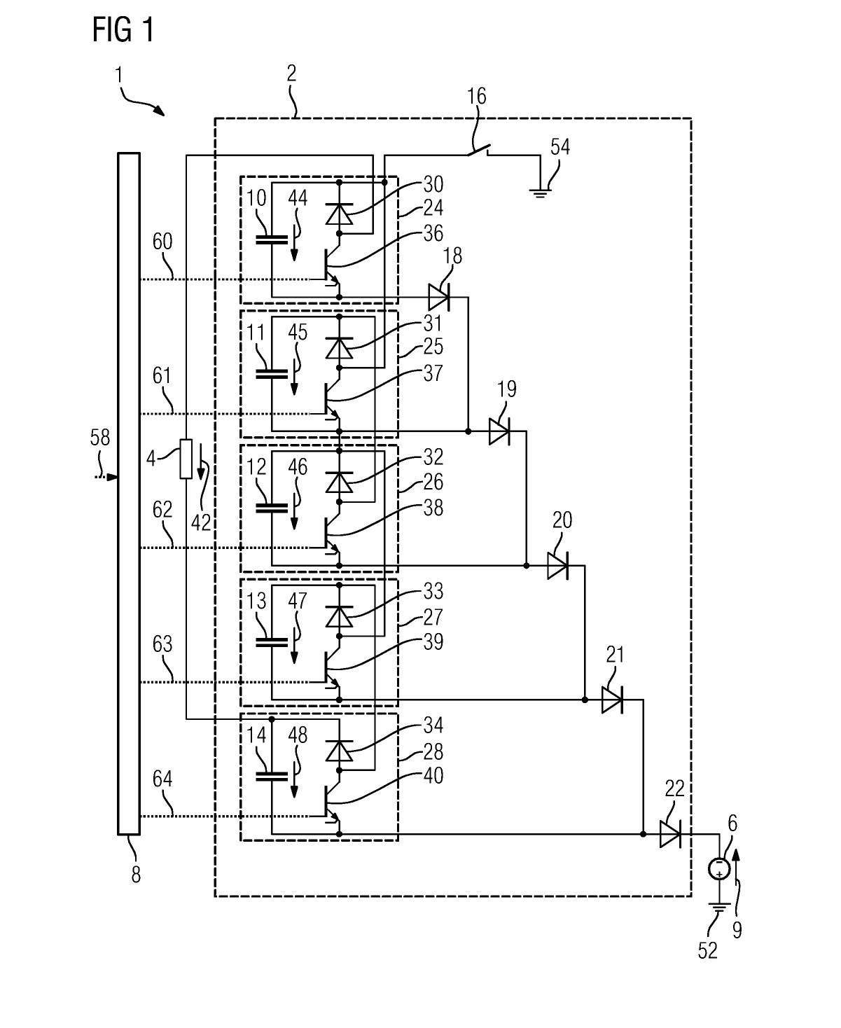

FIGS. 1 to 5 show a circuit diagram of a multilevel generator 1 with a multilevel converter 2, an electrical energy source 6, and a control device 8. In FIGS. 1 to 5, the same reference numbers indicate the same or similar elements. The multilevel generator 1 may be embodied as a Marx generator. In one embodiment, the multilevel generator 1 may be used in any multilevel generators such as, for example, multilevel H-bridge generators, flying-capacitor-multilevel generators, or diode-clamped multilevel generators.

The multilevel converter 2 supplies an electrical load 4 with electrical energy from the electrical energy source 6. For this, the multilevel converter 2 is driven by the control device 8.

In one embodiment, the electrical load 4 is a high-voltage load characterized in that the electrical load 4 is operated with voltages that are much higher than an open-circuit voltage of the electrical energy source. High-voltage loads of this kind represent, for example, X-ray sources in a computed tomography system or electric motors in hybrid vehicles.

In one embodiment, the electrical energy source 6 is a direct voltage source. The direct voltage output may be generated in any way. For example, the direct voltage may, for example, be provided by an inverter connected to a conventional domestic network with two or three phases or by a vehicle generator that, for example, outputs braking energy of the hybrid vehicle as direct voltage. For a clearer depiction of the exemplary embodiments, contrary to the convention with circuit diagrams, the negative potential (−) of the electrical energy source 6 is shown directed not toward the bottom of the diagram, but toward the top of the diagram. Viewed in the image plane, a corresponding source voltage 9 of the electrical energy source 6 does not point from top to bottom but from bottom to top.

The control device 8 will be described in more detail at a later point.

In one embodiment, the multilevel generator 2 includes buffer memories 10 to 14 that buffer the electrical energy from the electrical energy source 6 in a way described below. In the following, viewed in the plane of the drawing, the buffer memories are numbered from bottom to top as the first buffer memory 10 to the fifth buffer memory 14. Any type of energy storage systems may be used as the buffer memories 10 to 14 that may accept and store electrical energy and output the electrical energy on demand. Energy storage systems of this kind are, for example, capacitors or accumulators. In the figures, the buffer memories 10 to 14 are shown, by way of example, as capacitors.

The buffer memories 10 to 14 may be connected in parallel to the electrical energy source 6 by a charging switch 16 and by protective diodes 18 to 22. The individual cell voltages 44 to 48 of the buffer memories 10 to 14 may be increased to the value of the source voltage 9 and the buffer memories 10 to 14 charged in this way.

Each buffer memory 10 to 14 is wired into a storage cell 24 to 28, into each of which a free-wheeling diode 30 to 34 and a discharging switch 36 to 40 is also wired. The storage cells 24-28 may be, for example, energy output cells. The individual storage cells 24 to 28 are connected in series to the electrical load 4. The individual storage cells 24 to 28 may increase the level of a load voltage 42 at the electrical load 4 individually and independently of each other. For this, discharging switches 36 to 40 of a storage cell 24 to 28 in the series circuit may be selected from between the buffer memories 10 to 14 and the free-wheeling diodes 30 to 34. If the free-wheeling diode 30 to 34 is selected, the corresponding storage cell does not contribute to the load voltage 42. If the buffer memory 10 to 14 is selected, the load voltage 42 is increased by the cell voltage 44 to 48 output by the buffer memory 10 to 14.

In each storage cell 24 to 28, anodes of the free-wheeling diodes 30 to 34 are connected to the switch, and cathodes of the free-wheeling diodes 30 to 34 are connected to the buffer memory 10 to 14. In addition, an enclosed mesh is formed in that the buffer memory 10 to 14 is connected to the discharging switches 36 to 40.

FIGS. 1 to 5 show that the charging switch 16 is to be open if more than one discharging switch 36 to 40 is closed. Otherwise, the source voltage 9 would be included in the sum total of the effectively series-connected cell voltages 44 to 48 so that the electrical energy source 6 also represents an electrical load. In the open state of the charging switch 16, the protective diodes 18 to 22 provide that there is no current flow between the storage cells 24 to 28 and the electrical energy source 6.

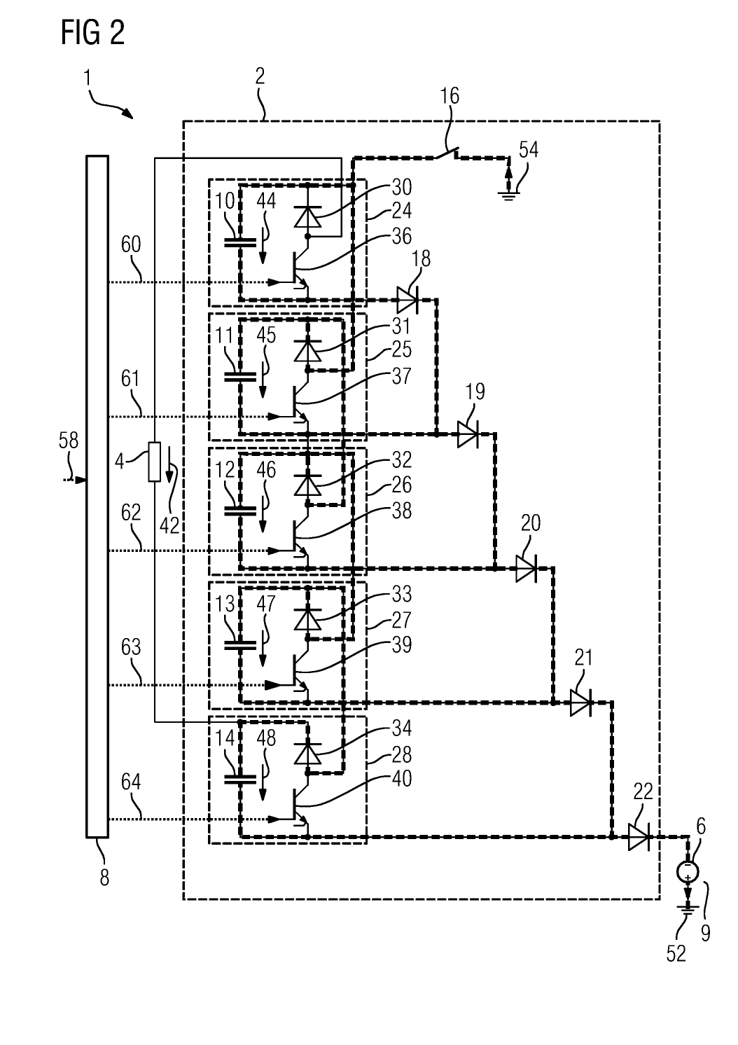

In FIG. 2, the effective current paths in the multilevel converter 2 during the charging phase of the storage cells 24 to 28 are shown with dotted lines.

Under the aforementioned condition that in the image plane, the source voltage 9 is directed upward, a charging current 50 flows into a mass point 52 connected to the electrical energy source and out of a mass point 54 connected to the first storage cell 10. Since the discharging switches 36 to 40 are open, the charging current 50 may only be allocated to the individual buffer memories 10 to 14 via the free-wheeling diodes 30 to 34 and flows back into the electrical energy source 6 via the protective diodes 18 to 22. If the buffer memories 10 to 14 are sufficiently charged, which in the case of a capacitor, for example, may be determined in advance with reference to a known charging behavior, the charging switch may be opened.

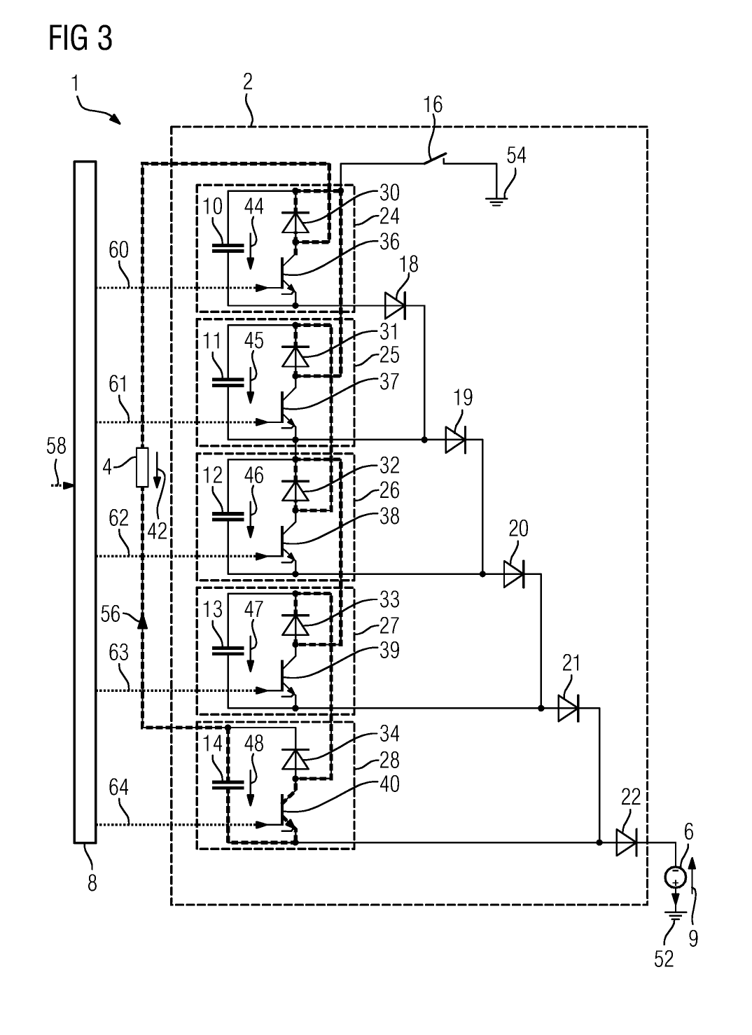

FIG. 3 shows the effective current path in the multilevel converter during an active phase, in which only the fifth buffer memory 14 is discharged.

In this case, only the fifth discharging switch 40 is closed, and all the other discharging switches 36 to 39 are open. In addition, if during the charging phase the fifth buffer memory 14 was an electrical load that accepted electric power from the electrical energy source 6, during the active phase the fifth buffer memory 14 is an electrical energy source that outputs the electrical energy to the electrical load 4. This is the reason for the name active phase. The direction of the cell voltage 48 of the fifth buffer memory 14 does not change on the transition between the charging phase and the active phase.

If the fifth buffer memory 14 functions as an electrical energy source, the fifth buffer memory 14 outputs a discharging current 56. The discharging current 56 leaves the fifth storage cell 28 and flows through the electrical load 4 into the first storage cell 24. At the first storage cell 24, the discharging current 56 enters the storage cell 24 between the free-wheeling diode 30 and the discharging switch 36. Since the discharging switch 36 is closed, the discharging current 56 may only be able to flow away again from the first storage cell 24 through the free-wheeling diode 30. The discharging current 56 flows out of the first storage cell 24 into the second storage cell 25 and passes through this in the same as the first storage cell 24. This is also repeated in the third and fourth storage cells 26, 27 until the discharging current 56 arrives at the fifth storage cell 28.

At the fifth storage cell 28, the corresponding discharging switch 40 is closed. Although the free-wheeling diode 34 is permeable, the negative potential of the fifth buffer memory 14 forces the discharging current 56 to flow back through the closed discharging switch 40 into the fifth buffer memory 14.

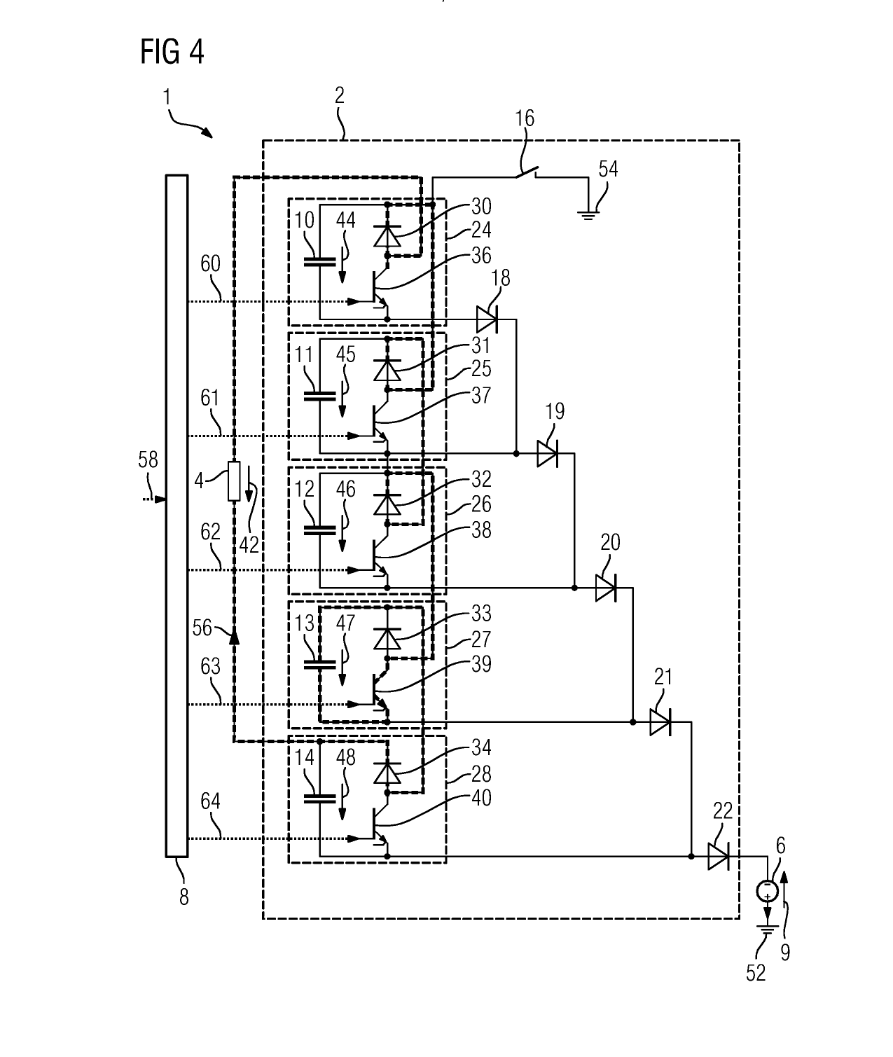

FIG. 4 shows the effective current path in the multilevel converter 2 during an active phase, in which only the fourth buffer memory 13 is discharged. The effective current path is subject to the same conditions as the effective current path in FIG. 3 and is therefore only mentioned incidentally.

In this case, only the fourth discharging switch 39 is closed, and all other discharging switches 36 to 38, 40 are open.

In this case, the discharging current 56 is provided by the fourth buffer memory 13. The discharging current 56 leaves the fourth storage cell 27 and enters the fifth storage cell 28. At the fifth storage cell 28, the discharging current 56 flows through the free-wheeling diode 34, leaves the fifth storage cell 28 and flows through the electrical load 4 and the first to third storage cells 24 to 26 back into the fourth storage cell 27.

The first to third storage cells 24 to 26 may output a discharging current 56 to the electrical load 4. If only a single storage cell 24 to 28 is applied to the electrical load 4, only a single cell voltage 44 to 48 is applied to the electrical load 4 as a load voltage 42.

FIG. 5 shows the effective current path in the multilevel converter 2 during an active phase, in which the fourth and fifth buffer memories 13 and 14 are discharged together. In this case, the effective current path is subject to the same conditions as the effective current path in FIG. 3 and is therefore only mentioned incidentally.

In FIG. 5, the fourth and fifth discharging switches 39, 40 are closed, and all other discharging switches 36 to 38 are open.

In this case, the discharging current 56 is provided by the fourth and the fifth buffer memory 13, 14. The discharging current 56 leaves the fourth storage cell 27 and enters the fifth storage cell 28. At the fifth storage cell 28, the discharging current 56 flows through the discharging switch 40 and the fifth buffer memory 14, leaves the fifth storage cell 28 and flows through the electrical load 4 and the first to third storage cells 24 to 26 back into the fourth storage cell 27.

Since two storage cells 27, 28 are applied to the electrical load 4, the sum total of the cell voltage 47, 48 of the fourth and fifth storage cells 27, 28 is applied to the electrical load 4. The load voltage 42 dropping at the electrical load 4 may be further increased if further discharging switches 36 to 38 in the remaining storage cells 24 to 26 are closed.

The buffer memories 10 to 14 of the individual storage cells 24 to 28 may be individually discharged through the discharging switches 36 to 40 and contribute to the output voltage 42 at the electrical load 4.

The discharging switches 36 to 40 are controlled via the control device 8. The control device 8 receives a quantized reference signal 58, the shape of which is to be emulated by the output voltage 42. The quantized reference signal 58 may be generated in any way, but in one embodiment, the quantized reference signal 58 is formed by a multidimensional pulse width modulation, with which, an analog reference signal is compared to a plurality of uniform pulse signals that are out of phase in relation to each other. Only the comparison results, for which the difference between the reference signal and the pulse signal is positive, raise the level of the quantized reference signal 58. One representative of this method is sine-triangle modulation.

On the basis of the quantized reference signal 58, the control device 8 generates a drive signal 60 to 64 for each discharging switch 36 to 40 in order to emulate the shape of the quantized reference signal 58 in the output voltage 42 with the individual storage cells 24 to 30.

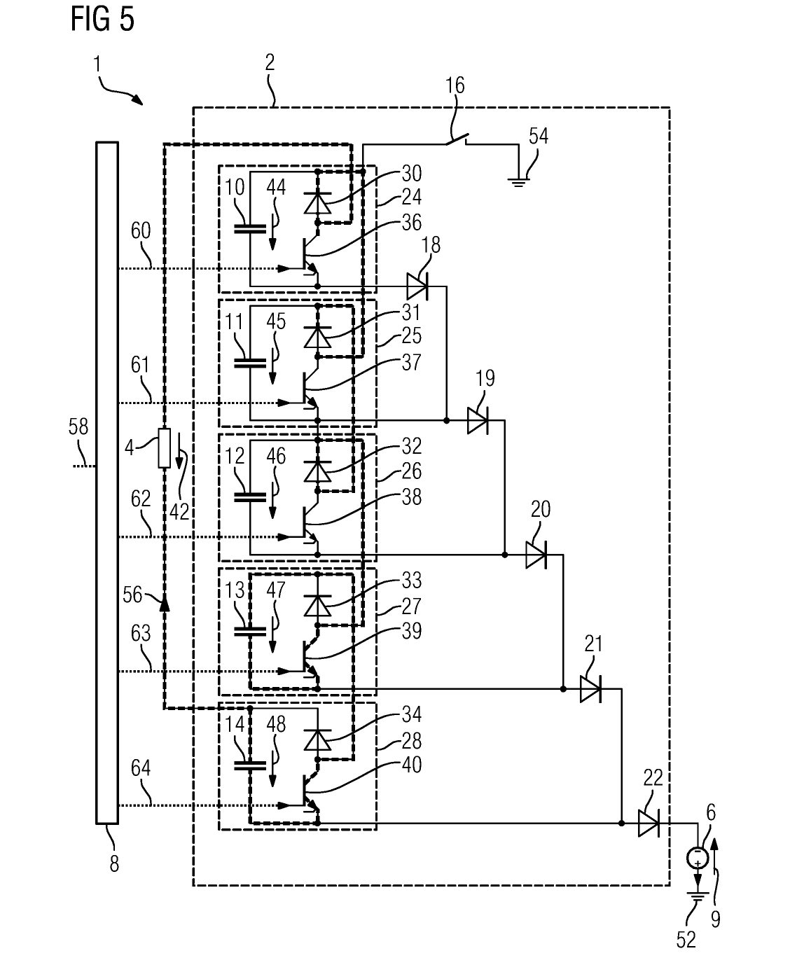

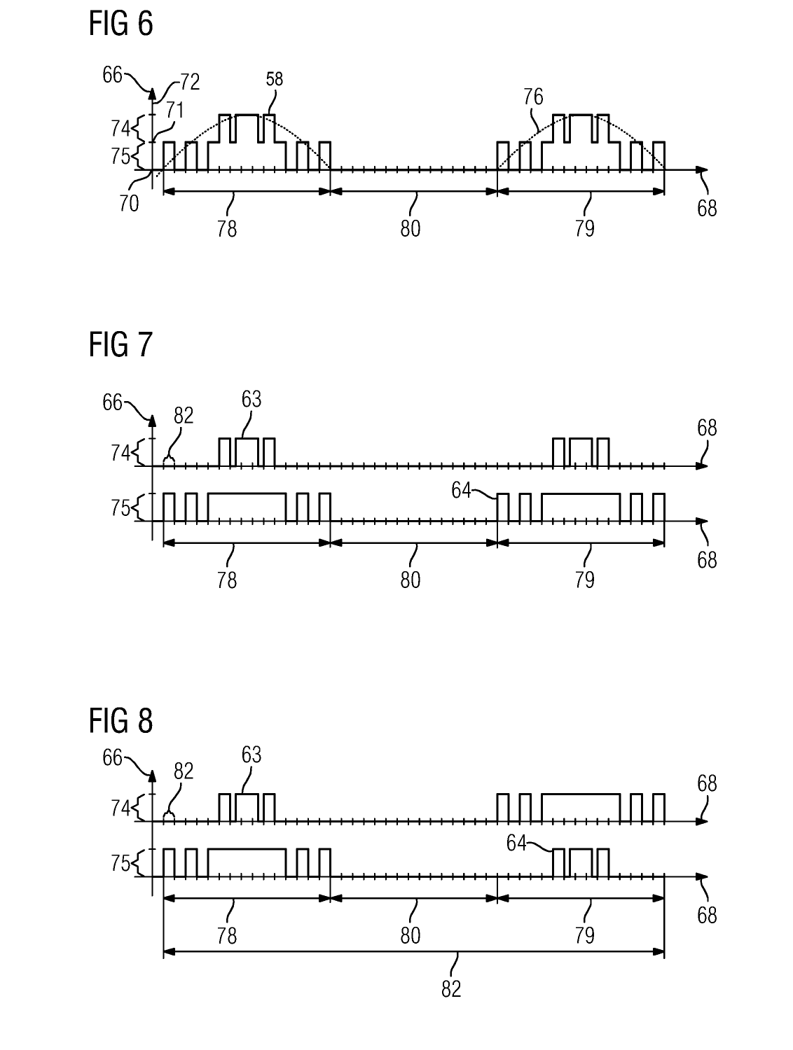

FIG. 6 is a diagram that shows the quantized reference signal 58. In the diagram in FIG. 6, a voltage 66 is plotted qualitatively over time 68. In FIG. 6, the same elements as shown in FIG. 5 are given the same reference numbers and are not described again.

The quantized reference signal 58 is characterized in that excursion values of the quantized reference signal 58 are only able to adopt individual grid values 70 to 71 determined by quantization levels 74, 75. In all the following explanations, a quantized reference signal 58 with two quantization levels 74, 75 is considered. Although, with the multilevel converter 2 shown in FIGS. 1 to 5, the shape of a quantized reference signal 58 with up to five quantization levels 74, 75 may be emulated in the output voltage 42.

For purposes of completeness, the analog reference signal 76, on which the quantized reference signal 58 is based, is shown as a dotted line in FIG. 6.

In addition, FIG. 6 shows the above-described active phases 78, 79 and the charging phases 80. The simultaneous generation of a positive and a negative half-wave in the output voltage 42 with a single multilevel converter 2 may not be technically feasible.

In order to emulate a complete sine-wave voltage as an output voltage 42 on the electrical load 4, an interconnection of two multilevel converters 2, with which one generates the positive and one generates the negative half-wave of the sine-wave voltage, is provided.

FIG. 7 shows an example of the drive signals 63, 64 that overall produce the quantized reference signal 58. In FIG. 7, elements that are the same as in FIG. 6 are given the same reference numbers and are not described again.

Under the aforementioned condition that the quantized reference signal has only two quantization levels 74, 76, for the emulation of the shape of the quantized reference signal 58 in the output voltage 42, only the fourth and fifth storage cells 27, 28 are driven and the corresponding buffer memories 13, 14 discharged.

As shown in FIG. 7, the fourth storage cell 27 takes over the emulation of the shape of the upper quantization level 74 of the quantized reference signal 58 in the output voltage 42, since the corresponding drive signal 63 for the discharging switch 39 has the shape of the upper quantization level 74 of the quantized reference signal 58. Correspondingly, the fifth storage cell 28 takes over the emulation of the shape of the lower quantization level 75 of the quantized reference signal 58 in the output voltage 42.

The sum total on-period over the two active phases 78, 79 of the fourth storage cell 27 is much smaller than the fifth storage cell 28 because the fourth storage cell 27 is driven less frequently than the fifth storage cell 28. For example, the fourth storage cell 27 is overall switched on over 8 time units 82, while the fifth storage cell 28 is switched on over 22 time units 82.

In addition, the drive signal 63 of the fourth storage cell 27 has fewer edges than the drive signal 64 of the fifth storage cell 28. For example, the fourth storage cell 27 passes through a total of 6 switching operations (e.g., a switching operation is a positive or a negative edge in the drive signal 63, 64), while the fifth storage cell 28 passes through 10 switching operations in total.

This has the result that the buffer memories 13 of the fourth storage cell 27 are loaded less than the buffer memories 14 of the fifth storage cell 28. Similarly, the buffer memories 13 of the fourth storage cell 27 are discharged less than the buffer memories 14 of the fifth storage cell 28.

In order to dimension the individual components of the multilevel converter 2 to last as long as possible, the storage cells 24 to 28 may be designed such that the storage cells 24 to 28 may be used at every position in the multilevel converter 2 and may not be destroyed by the losses that occur.

Additionally, switching frequency limitation is provided to reduce the switching losses. In addition, the buffer memories 10 to 14 are designed such that, regardless of the position in the module, the voltage dip at the storage cells 24 to 28 caused by the discharging current 56 remains acceptably small. However, this procedure provides that the majority of storage cells 24 to 28 in the multilevel converter 2 are over-dimensioned, thus increasing the cost of the module.

Although one possible remedy would be to dimension each storage cell 24 to 28 individually for the planned position in the multilevel converter 2, this would result in nX different storage cells 24 to 28 and hence lower quantities of each storage cell 24 to 28, thus entailing higher production costs. The production complexity would also be higher, since each cell would have a fixed mounting location. Similarly, the multilevel converter 2 may be designed as non-modular (e.g., providing that output voltages 42 of any magnitude are possible using a concatenation of the storage cells 24 to 28, as desired), since each storage cell 24 to 28 would be dimensioned separately.

Therefore, viewed over a predetermined period, in order to emulate the shape of a quantization level 74 of the quantized reference signal 58, a contribution from not one single storage cell 24 to 28 but from several storage cells 24 to 28 together is provided. In this way, the energy flow from the electrical energy source 6 may be allocated to the electrical load 4 via the individual storage cells 24 to 28 such that the loads on the storage cells 24 to 28 are also balanced.

FIG. 8 shows a further example of the drive signals 63, 64 that overall produce the quantized reference signal 58. In FIG. 8, elements that are the same as those in the FIG. 7 are given the same reference numbers and are not described again. FIG. 8 assumes the generation of an output voltage 42 with the shape of the two-level quantized reference signal 58 from FIG. 6.

In this example, the switching losses and the current loads are allocated to the individual storage cells 24 to 28 in the multilevel converter 2.

One condition for this is that the shape of the quantized reference signal 58, and hence the shape of the output voltage 4, is repeated or is at least similar over several active phases 78, 79.

The method to generate the drive signals 63, 64 substantially corresponds to the method explained with respect to FIG. 7.

After each active phase 78, 79, however, the quantization levels 74, 75 to be generated of the quantized reference signal 58 are exchanged in the drive signals 63, 64 such that, averaged over a predetermined period 82 of two active phases, each storage cell 27, 28 has generated each quantization level 74, 75 of the quantized reference signal 58. This provides that, with a constant shape of the output voltage 42 over several active phases 78, 79 averaged over the predetermined period 82, the same load on both storage cells 27, 28 is provided. If, in a way not shown in FIG. 8, a reference signal 58 extending over two quantization levels 74, 75 is generated, the quantization levels 74, 75 of the quantized reference signal 58 of the individual storage cells 24 to 28 may be exchanged such that, over the predetermined period 82, two specific storage cells 24 to 28 have approximately experienced the load corresponding to the average load of all storage cells 24 to 28.

If the shape of the quantized reference signal 58 and hence shape of the output voltage 42 is known, the load of the individual storage cells 24 to 28 may be determined once in advance. On this basis of this, the sequence may be fixed in a memory logic circuit, for example, in the control unit 8. This memory logic circuit may then be used to exchange the generated drive signals 60 to 64 for the individual storage cells 24 to 28 of the multilevel converter 2 after each active phase 78, 79.

More simply, the drive signals 60 to 64 may be exchanged sequentially. The result of this is that the drive signals 60 to 64 for each cell repeat all the active phases 78, 79 corresponding to the number of storage cells 24 to 28.

The example in FIG. 8 shows that over the two active phases 78, 79 shown and hence over the predetermined period 82, the sum total on-period of the fourth storage cell 27 is the same as the sum total on-period of the fifth storage cell 28, since, although the fourth storage cell 27 is driven less frequently in the first active phase 78 than the fifth storage cell 28, in the second active phase 79, the fourth storage cell 27 is driven just as frequently as the fifth storage cell 28 in the first active phase 78 and vice versa. Also, the fifth storage cell 28 is driven as frequently as the fourth storage cell 27 in the first active phase 78. For example, both storage cells 27 are overall switched on over 15 time units 82 over the predetermined period 82.

The same observation may be made with reference to the edges of the drive signals 63, 64. Hence, both storage cells 27, 28 pass through 8 switching operations in total.

In a further development of the example according to FIG. 8, the switching losses for each switching operation and the losses due to the current load over the on-period in dependence on the cell voltage 44 to 48 and with a varying electrical load 4 may also be determined in dependence on the electrical load 4 for each quantization level 74, 75 of the quantized reference signal 58. Additionally, the control device 8 may contain an individual counter for the switching operations of each storage cell 24 to 28 and performs a time measurement for the on-period of each storage cell 24 to 28. The counters and time measurement may also be operated individually for each active phase 78, 79. The data from the counters and the time measurements and the previous losses determined may be used to determine the total losses in each storage cell 24 to 28 or in the individual components of each storage cell 24 to 28.

From the total losses, algorithmic methods may be used to determine the quantization levels 74, 75 of the quantized reference signal 58 to be allocated to the drive signals 60 to 64 for each active phase 78, 79 separately so that the average load of all storage cells 24 to 28 is the same on average. If, for example, semiconductor switches are used as discharging switches 36 to 40, at higher frequencies, the switching losses are greater than the conduction losses. If capacitors are used as buffer memories 10 to 14, the conduction losses in the capacitors are also lower than the losses in the semiconductor switches, and so, the switching losses in the semiconductor switches may only be taken account of. In this case, there is no need for a time measurement to determine the on-periods.

However, a drawback of this variant is that the shape of the output voltage 4 and hence the shape of the quantized reference signal 58 may not change over several active phases 78, 79. In addition, no temporal peak loads are reduced, since the losses of the most greatly loaded storage cell 24 to 28 within an active phase 78, 79 are not allocated to a less strongly loaded storage cell 24 to 28. If the multilevel converter 2 has a modular design, all storage cells 24 to 28 also are dimensioned with respect to the temporal peak loads. This is particularly important if capacitors are used as buffer memories 10 to 14, since otherwise, the cell voltage 44 to 48 would be too small due to discharge at individual storage cells 24 to 28.

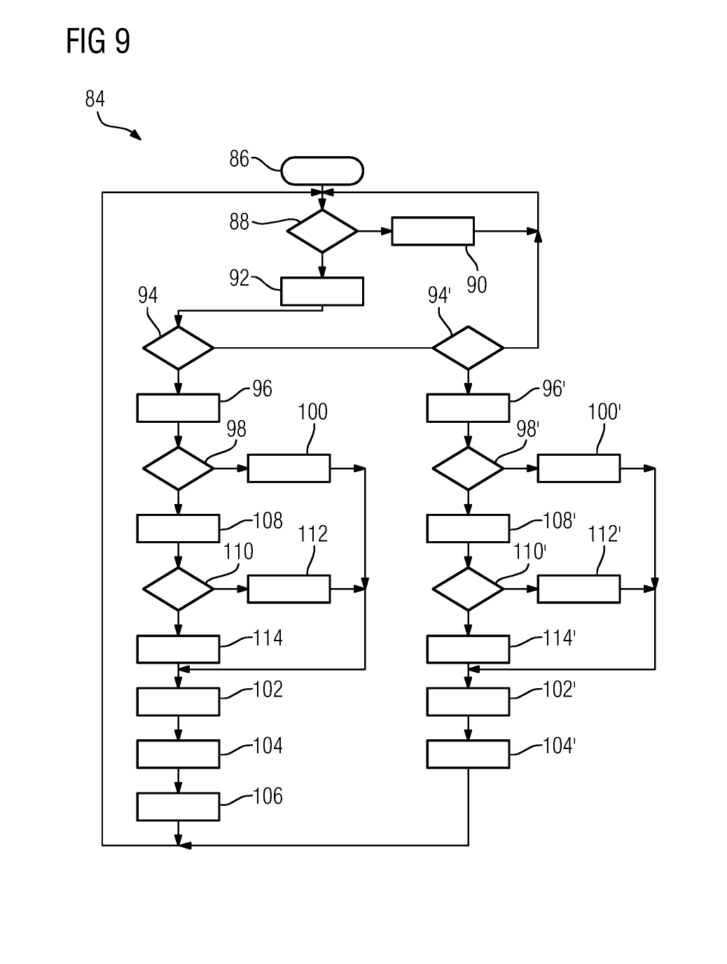

FIG. 9 shows the acts of a method 84 to generate alternative drive signals 63, 64 to those in FIGS. 7 and 8. The overall method 84 is performed by the control device 8 shown in FIG. 1. For the embodiment of the method 84, the control device 8 contains a processor (not shown) and a timer (not shown) for each storage cell 24 to 28 and a counter (not shown) for each storage cell 24 to 28. While the control device 8 may determine the on-periods of each storage cell 24 to 28 individually with the timers, with the counters, the control device 8 may determine the number of switching operations performed by each storage cell 24 to 28.

The method 84 may be implemented in the control device 9 as a function on a logic module containing counters and timers and inserted between an already known control signal generation and a similarly known driving circuit for the storage cells 24 to 28.

The method 84 may reduce the predetermined period 82 to the active phases 78, 79 of the quantized reference signal 58.

The control device 8 starts the method 84 in act 86 with the previously explained generation of the quantized reference signal 58 from an analog reference signal 76 based, for example, on sine-triangle modulation. The quantized reference signal 58 may optionally be made up of individual partial signals according to FIG. 7. Each partial signal corresponds to the temporal course of one of the quantization levels 74, 75 of the quantized reference signal 58.

In act 88, the control device 8 starts an important part of the method 84 by checking whether the multilevel converter 2 is in an active phase 78, 79.

If the multilevel converter 2 is outside an active phase 78, 79, in act 90, the control device 8 returns the counters and timers back to a standard value and returns to act 88 until the multilevel converter 2 is transferred to an active phase 78, 79.

If the multilevel converter 2 has transferred to an active phase 78, 79, in the acts 92, 94, 94′, the detection and evaluation of the edges of the quantized reference signal 58 or alternatively, the edges of the partial signals is performed. In act 92, the control device 8 detects the edge. In act 94, the control device 8 checks whether the edge is positive and in act 94′ checks whether the edge is negative. If, for example, due to an error, the detected edge is neither positive nor negative, the control device 8 returns to act 88.

The following explains the individual acts following a detection of a positive edge in the quantized reference signal 58 together with the acts following a detection of a negative edge in the quantized reference signal 58. Explicit references to common features and differences between the two branches of the method will be made at the appropriate places.

If the control device 8 detects a positive edge in act 94 or a negative edge in act 94′, the control device 8 uses the timers in act 96 to compare the on-periods of the already active storage cells 24 to 28 with discharging switches 36 to 40 that are closed at the time of the comparison, or the control device 8 uses the timers in act 96′, to compare the on-periods of the inactive storage cells 24 to 28 with discharging switches 36 to 40 that are open at the time of the comparison. The timers (e.g., the on-periods) may be used to measure the line losses because the longer the buffer memory 10 to 14 of a storage cell 24 to 28 is discharged, the higher the memory losses that occur.

This is taken into account in acts 98, 100 or 98′, 100′. In the case of a positive edge (e.g., branch of the method from act 94), in act 98, the control device 8 checks whether the two storage cells 24 to 28 with the currently shortest on-periods have identical on-periods. If there is a clear storage cell 24 to 28 with a shortest on-period, the control device 8 selects the storage cell in act 100, activates the storage cell in act 102, activates the corresponding timer in act 104 and increments the corresponding counter in act 106. The control device 8 returns to act 88. In the case of a negative edge (e.g., branch of the method from act 941, the control device 8 checks in act 98′ whether the two storage cells 24 to 28 with the currently longest on-periods have identical on-periods. If there is a clear storage cell 24 to 28 with a longest on-period, the control device 8 selects the storage cell in act 100′, switches the storage cell off in act 102′ and stops the corresponding timer in act 104′. Optionally, in a way not shown in FIG. 9, the corresponding counter may be incremented for a switching operation. This is not necessary, however, since a starting operation also causes a shutdown operation so that the two switching operations are dependent on each other, and therefore, the total number may be determined by counting one of the two switching operations. The control device 8 either returns to act 104′ or after an incrementation (not shown) of the counter belonging to the switched off storage cell 24 to 28, or returns to act 88 after act 104′.

In acts 102, 102′, the activation of the storage cell 24 to 28 or the switching off of the storage cell 24 to 28 is characterized in that the control device 8 activates or deactivates the drive signal 60 to 64 corresponding to the storage cell 24 to 28.

If in act 98, at least two storage cells 24 to 28 with the currently shortest on-periods or in act 98′, at least two storage cells 24 to 28 with the currently longest on-periods have identical on-periods, in act 108 or in act 108′, the control device 8 checks the number of switching operations of the storage cells 24 to 28 with the longest or shortest on-periods in questions with reference to the counters.

In acts 110 and 110′, the control device 8 checks uniformly with reference to the counters whether the storage cells 24 to 28 with the shortest or longest on-periods in question include a storage cell 24 to 28 with fewer switching operations. If this is the case, the control device 8 selects from the storage cell 24 to 28 in question with the fewest switching operations (e.g., with the lowest associated counter value) and proceeds further with act 102 or with act 102′ in the way described above.

If a storage cell 24 to 28 with the shortest on-periods and/or with the fewest switching operations may not be found with reference to acts 98, 98′ or with reference to acts 110, 110′, in act 114 or in act 114′, the control device 8 arbitrarily selects a storage cell 24 to 28 from the plurality of specific storage cells 24 to 28 with the shortest on-periods and/or with the fewest switching operations and proceeds further with act 102 or with act 102′ in the way described above.

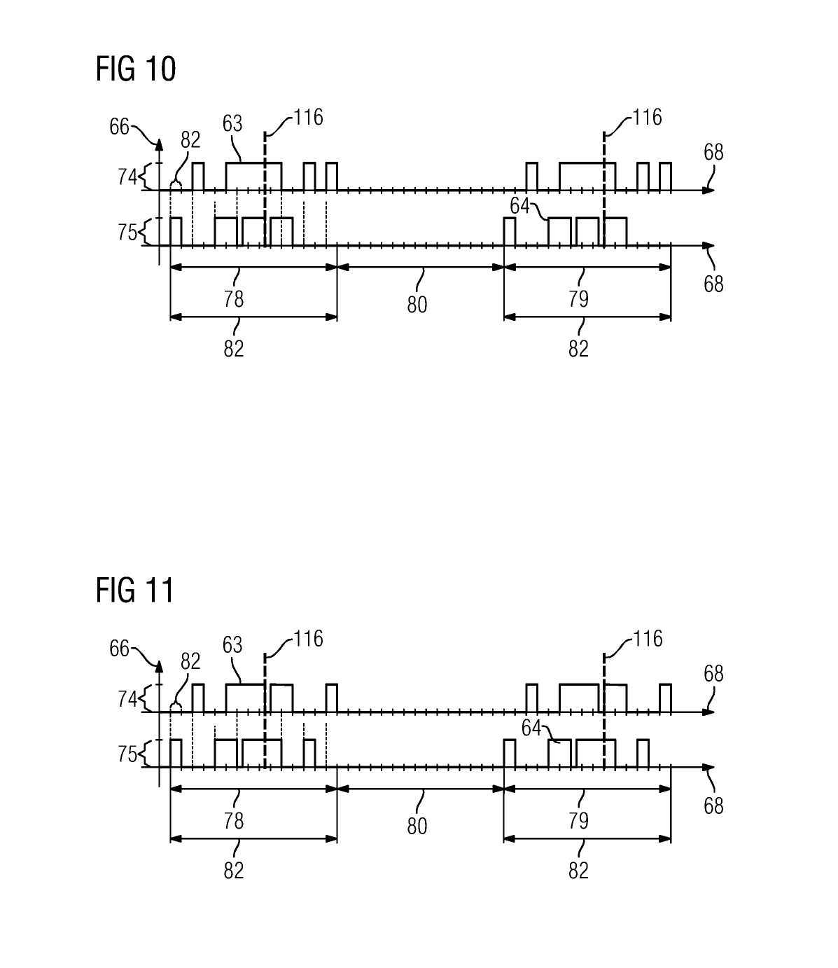

FIG. 10 shows two drive signals 63, 64 that overall produce the quantized reference signal 58. In FIG. 10, elements that are the same as in the preceding figure are given the same reference numbers and are not described again. In addition, in FIG. 10, the generation of an output voltage 42 with the shape of the two-level quantized reference signal 58 from FIG. 6 is assumed.

FIG. 10 shows that, unlike the method described with reference to FIG. 8, the method 84 results in a limitation of the predetermined period 82 to the active phase 78, 79 of the quantized reference signal 58. In this way, not only are the temporal loads between the individual storage cells 24 to 28 of the multilevel converter 2 counterbalanced with each other, the peak loads of the individual storage cells 24 to 28 of the multilevel converter 2 during an active phase may also be counterbalanced with each other and thus effectively reduced.

As FIG. 10 shows, the second positive edge in the quantized reference signal 56 has the result that the fourth and the fifth storage cells 27, 28 change with respect to the contribution with their cell voltages 47, 48 to the load voltage 42, although both positive edges belong to the lower quantization level 75 of the quantized reference signal 58.

The drawback with the method 84 is that the method prioritizes either the on-periods only or the switching operations only. However, if the prioritized parameters values for each storage cell 24 to 28 differ greatly, this will not be taken into account by the method 84, but a decision will always be made with reference to the prioritized parameter.

This will be explained with reference to the time point 116 shown in FIG. 10. At time 116, a negative edge occurs in the quantized reference signal 56. This results in one of the two drive signals being switched off. While for the fourth drive signal 63 at the time point 116, 4.5 time units 82 and 2 switching operations are counted, for the fifth drive signal 64 at the time point 116, 5 time units 82 and 3 switching operations are counted. Since the fourth drive signal 63 has a lower on-period and the method 84 prioritizes the on-periods in act 98′, in act 100′, the method 84 switches the fifth drive signal 64 off.

FIG. 11 shows the two drive signals 63, 64 that overall produce the quantized reference signal 58. In FIG. 11, elements that are the same as in FIG. 10 are given the same reference numbers and are not described again. In addition, in FIG. 11, the generation of an output voltage 42 with the shape of the two-level quantized reference signal 58 from FIG. 6 is assumed.

FIG. 11 shows a method 84, with which, with respect to the on-periods, the decision made with respect to the shortest or longest on-period is not hard but soft within a tolerance band. As shown in FIG. 11, this results, at the time point 116, in the switching off of the fourth drive signal 63 and not of the fifth drive signal 64 in act 98′.

The tolerance Δ in the on-period introduced in acts 98, 98′ of the method 84 has the result that storage cells 24 to 28 with an on-period t_{d}±Δ are considered to be identical so that the number of the switching operations is taken into account in the case of parity of the on-period of a plurality of storage cells 24 to 28 and in the case of slight differences in the on-period of a plurality of storage cells 24 to 28.

The prioritization of the on-period or the switching operations is applicable and dependent upon where, for example, the higher losses are expected or whether uniform discharge of the individual cells 24 to 28 is desired.

Prioritizing the parameter with the expected higher losses has the advantage that, for example, the method 84 breaks off after one decision-making act 98, 98′ and does not move on to another decision-making act 110, 110′.

Alternatively, the switching operations may be prioritized, and only the on-period in the case of the same or almost the same number of switching operations may be checked.

If it is technically inadvisable to take into account the on-period and the number of the switching operations for the generation of the drive signals 60 to 64, only the on-period or only the number of switching operations may be used for the decision regarding the next storage cell 24 to 28 to be driven.

The method described in FIGS. 9 to 11 may also be used to allocate the losses to the individual storage cells 24 to 28 during the active phases 78, 79 and to discharge the buffer memories 10 to 14 more uniformly. This makes better utilization of the total capacitance of the individual buffer memories 10 to 14, regardless of whether the individual buffer memories 10 to 14 are capacitors or accumulators. The capacitance values of the buffer memories 10 to 14 may be reduced and/or the stability of the load voltage 4 improved.

This enables the same dimensioning of all storage cells 24 to 28. As a result, the multilevel converter 2 may have a modular design, and the costs per storage cell 24 to 28 and hence per multilevel converter 2 may be reduced. The uniform load also provides that approximately the same lifetime may be expected for the individual storage cells 24 to 28.

The allocation of the switching losses to the individual storage cells 24 to 28 also enables the switching frequencies of the cells to be increased. This also enables the frequency of the load voltage 4 to be significantly increased.

A further advantage of method 84 explained with reference to FIGS. 9 to 11 is that additional storage cells 24 to 28 may be used to increase the switching frequencies that would not be necessary with respect to the maximum load voltage 4. However, the losses may be allocated to the additional storage cells 24 to 28, and hence, the switching frequency is additionally increased. Since this would provide that the on-periods are also allocated to the additional storage cells 24 to 28, a greater total capacitance would not be necessary, thus enabling a reduction in the capacitance of the buffer memories 10 to 14 and not incurring any additional costs for the buffer memories 10 to 14.

In a further embodiment of the method 84, nonlinearities in the electrical load may be taken into account. This is advantageous, for example, if due to the greatly varying output current, allocation of the on-periods and/or switching operations to the individual storage cells 24 to 28 is not sufficient. In order to still allocate the load, the discharging current 56 carried over the electrical load is measured. The on-period may be weighted with the measured discharging current 56 in each case and optionally with a factor.

The weighting may be performed in the same or an alternative way for the switching operations.

In another alternative embodiment of the method 84, the selection of the next storage cell 24 to 28 to be driven via a drive signal 60 to 64 may be performed on the basis of the cell voltages 44 to 48. In the method 84, in acts 96, 96′, the cell voltages 44 to 48 of the individual storage cells 24 to 28 are measured. A comparison of the individual cell voltages 44 to 48 is used in act 98 to determine the storage cell 24 to 28 with the highest cell voltage 44 to 48 or in act 98′ to determine the storage cell 24 to 28 with the lowest cell voltage 44 to 48, and in act 100 to select the storage cell 24 to 28 with the highest cell voltage 44 to 48, or in act 100′ with the lowest cell voltage 44 to 48. From there, the method is continued as described above.

Alternative to selection based on the on-periods and/or the number of the switching operations or supplementary thereto, the selection of the storage cells 24 to 28 based on the cell voltages 44 to 48 may be performed with any type of prioritization in the method 84.

The selection of the storage cells 24 to 28 based on the cell voltages 44 to 48 provides uniform discharge of the buffer memories 10 to 14 of the individual storage cells 24 to 28.

In addition, even in the case of linear electrical loads 4, generation of the drive signals 60 to 64 and hence the performance of the method 84 based only on switching operations and/or based on the on-of periods of the storage cells 24 to 28 may not be sufficient. This may occur due to the increased discharging current 56 at an elevated load voltage 42 and, simultaneously, non-optimum allocation of the individual drive signals 60 to 64 that overall produce the quantized reference signal 58, to the storage cells 24 to 28 over the active phases 78, 79.

In order to avoid this, even with linear loads in acts 98, 98′ or in acts 100, 100′ of the method 84, the switching operations and/or the on-periods may be weighted. Since, with a linear electrical load 4, the discharging current 56 is dependent upon the load voltage 42 and hence upon the number of active storage cells 24 to 28, the switching operations and/or the on-periods, for example, may be weighted with the number of the currently active storage cells 24 to 28 and/or with the cell voltage 44 to 48 and optionally with a factor. Measurement of the discharging current may then be dispensed with.

One embodiment of the method 84 may take the fact the loads on the switching on and switching off of the discharging switches 36 to 40 are different into account. For example, when a storage cell 24 to 28 is switched on, the flows may be lower than on switching off, or with the same condition, due to a slower switching off time, the switching-off process is associated with more losses than the switching-on process.

This difference may be taken into account by an additional counting of the switching-off processes, and the accuracy of the harmonization of the loads of the storage cells 24 to 28 may be further improved. For this, the switching-on processes in the storage cells 24 to 28 are weighted differently than the switching-off processes of the storage cells 24 to 28.

The weighting may take place immediately. No additional counters are then required.

In a multilevel converter, at least two drive signals of different storage cells contribute to a quantization level of a quantized reference signal for the multilevel converter in a predetermined period.

Although the invention is illustrated and described in more detail by the preferred exemplary embodiment, the invention is not restricted by the disclosed examples. The person skilled in the art may derive other variations therefrom without leaving the scope of protection of the invention.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for the generation of drive signals for a multilevel generator comprising a plurality of cells that are switchable independently of each other, each cell of the plurality of cells operable to output a cell voltage based on a respective drive signal, wherein the drive signals of the plurality of cells overall are operable to output a multilevel quantized reference signal, the method comprising:
splitting the multilevel quantized reference signal such that at least two of the drive signals contribute to a quantization level of the quantized reference signal in a predetermined period, the at least two drive signals being of different cells of the plurality of cells.

2. The method as claimed in claim 1, wherein the quantized reference signal comprises a plurality of partial signals, the number of the plurality of partial signals being smaller than or equal to the number of the plurality of cells.

3. The method as claimed in claim 2, wherein the quantized reference signal and the plurality of partial signals are periodic,
wherein the method further comprises allocating the periodic partial signals to the drive signals in each period of the quantized reference signal, and
wherein the predetermined period is a multiple of the period of the quantized reference signal.

4. The method as claimed in claim 2, further comprising splitting the quantized reference signal in the drive signals such that drive times of individual cells of the plurality of cells in the predetermined period are the same.

5. The method as claimed in claim 4, further comprising determining a positive edge or a negative edge of the quantized reference signal or the plurality of partial signals in the predetermined period; and
activating or deactivating the drive signal belonging to a cell of the plurality of cells with the shortest or longest drive time.

6. The method as claimed in claim 5, further comprising activating or deactivating the drive signal belonging to a cell of the plurality of cells with the fewest switching operations.

7. The method as claimed in claim 6, further comprising determining the cell with the shortest or longest drive time before the cell with the fewest switching operations.

8. The method as claimed in claim 6, further comprising resetting a number of the switching operations, the drive times, or the switching operations and the drive times of each cell of the plurality of cells following the expiration of the predetermined period.

9. The method as claimed in claim 7, wherein the drive time of two cells of the plurality of cells is the same when the respective drive times lie within a predetermined tolerance band.

10. The method as claimed in claim 7, wherein cells of the plurality of cells with the fewest switching operations are determined before the cell with the shortest or longest drive time.

11. The method as claimed in claim 7, further comprising weighting the drive times or the number of the switching operations of the individual cells with a weighting factor.

12. The method as claimed in claim 11, wherein the weighting factor is dependent on an output current of the multilevel generator, an output voltage of the multilevel generator at a time of a determination of the drive time, or a combination thereof.

13. The method as claimed in claim 4, further comprising activating or deactivating the drive signal belonging to a cell of the plurality of cells with the fewest switching operations.

14. The method as claimed in claim 7, further comprising resetting a number of the switching operations, the drive times, or the switching operations and the drive times of each cell of the plurality of cells following the expiration of the predetermined period.

15. The method as claimed in claim 8, wherein the drive time of two cells of the plurality of cells is the same when the respective drive times lie within a predetermined tolerance band.

16. The method as claimed in claim 9, wherein cells of the plurality of cells with the fewest switching operations are determined before the cell with the shortest or longest drive time.

17. The method as claimed in claim 9, further comprising weighting the drive times or the number of the switching operations of the individual cells with a weighting factor.

18. A device configured for generating drive signals for a multilevel generator comprising a plurality of cells that are switchable independently of each other, each cell of the plurality of cells operable to output a cell voltage based on a respective drive signal, wherein the drive signals of the plurality of cells overall are operable to output a multilevel quantized reference signal, the device being further configured to:
split the multilevel quantized reference signal such that at least two of the drive signals contribute to a quantization level of the quantized reference signal in a predetermined period, the at least two drive signals being of different cells of the plurality of cells.

19. A circuit comprising:
a multilevel generator with cells that are switchable independently of each other, each of the cells operable to output a cell voltage based on a respective drive signal; and
a device configured to:
generate the drive signals for the multilevel generator, wherein the drive signals of the cells overall are operable to output a multilevel quantized reference signal; and
split the multilevel quantized reference signal such that at least two of the drive signals contribute to a quantization level of the quantized reference signal in a predetermined period, the at least two drive signals being of different cells of the plurality of cells.

20. An X-ray device comprising:
an X-ray source; and
a circuit operable to supply the X-ray source with electrical energy, the circuit comprising:
a multilevel generator with cells that are switchable independently of each other, each of the cells operable to output a cell voltage based on a respective drive signal; and
a device configured to:
generate the drive signals for the multilevel generator, wherein the drive signals of the cells overall are operable to output a multilevel quantized reference signal; and
split the multilevel quantized reference signal such that at least two of the drive signals contribute to a quantization level of the quantized reference signal in a predetermined period, the at least two drive signals being of different cells of the plurality of cells.
